(19) United States
(12) Patent Application Publication
(10) Pub. No.: US 2024/0297108 A1
(43) Pub. Date: Sep. 5, 2024

(54) ELECTRONIC ELEMENT MOUNTING BOARD, ELECTRONIC COMPONENT, AND ELECTRONIC APPARATUS

(71) Applicant: KYOCERA CORPORATION, Kyoto (JP)

(72) Inventor: Kanae HORIUCHI, Kyoto-shi (JP)

(73) Assignee: KYOCERA Corporation, Kyoto-shi, Kyoto (JP)

(21) Appl. No.: 18/278,501

(22) PCT Filed: Feb. 24, 2022
(86) PCT No.: PCT/JP2022/007582

§ 371 Date: Aug. 23, 2023

(30) Foreign Application Priority Data
Feb. 26, 2021 (JP) 2021-031019

(51) Int. Cl. H01L 23/498; H01L 23/00; H01L 23/13

(52) U.S. Cl. CPC H01L 23/49838; H01L 23/13; H01L 24/48; H01L 24/49; H01L 2224/48091; H01L 2224/48227; H01L 2224/49176

(57) ABSTRACT

An electronic element mounting board includes a bottom portion including a mounting surface, a side portion positioned surrounding the mounting surface of the bottom portion, and a conductor forming a part of the side portion. The side portion includes a first surface located on a side of the mounting surface and a recessed portion surface recessed from the first surface. The conductor includes an outer surface located on the recessed portion surface. The electronic element mounting board further includes a coating film covering the outer surface. The optical reflectance of the coating film is lower than the optical reflectance of the conductor.

### TECHNICAL FIELD

The present disclosure relates to an electronic element mounting board, an electronic component including the electronic element mounting board, and an electronic apparatus including the electronic component.

### BACKGROUND OF INVENTION

Patent Document 1 discloses a package on which an electronic element is mounted, the package including a via conductor for connecting an electrode on a front surface side and an electrode on a bottom surface side.

### CITATION LIST

### Patent Literature

Patent Document 1: JP 2009-170499 A

### SUMMARY

In one aspect of the present disclosure, an electronic element mounting board includes: a bottom portion including a mounting surface on which an electronic element is mounted; a side portion positioned surrounding the mounting surface of the bottom portion and including a first surface located on a side of the mounting surface and a recessed portion surface recessed from the first surface; and a conductor forming a part of the side portion and including an outer surface located on the recessed portion surface.

In another aspect of the present disclosure, an electronic element mounting board includes: a bottom portion including a mounting surface on which an electronic element is mounted; a side portion positioned surrounding a mounting surface of the bottom portion and including a first surface located on a side of the mounting surface; a conductor including an outer surface located up to the first surface on a part of the side portion; and a coating film covering the outer surface, in which an optical reflectance of the coating film is lower than an optical reflectance of the conductor.

### BRIEF DESCRIPTION OF THE DRAWINGS

FIG. 1 is an enlarged schematic plan view of the vicinity of a recessed portion surface in an electronic element mounting board according to a first embodiment of the present disclosure.

FIG. 2 is a schematic plan view of an electronic component according to the first embodiment of the present disclosure.

FIG. 3 is a schematic cross-sectional view of the electronic component according to the first embodiment of the present disclosure.

FIG. 4 is enlarged schematic views of the recessed portion, each illustrating an example of the recessed portion surface in the electronic element mounting board according to the first embodiment of the present disclosure.

FIG. 5 is a schematic cross-sectional view of an electronic component according to a variation of the first embodiment of the present disclosure.

FIG. 6 is an enlarged schematic plan view of the vicinity of a recessed portion surface in an electronic element mounting board according to a second embodiment of the present disclosure.

FIG. 7 is an enlarged schematic plan view of the vicinity of a recessed portion surface in an electronic element mounting board according to a third embodiment of the present disclosure.

FIG. 8 is an enlarged schematic plan view of the vicinity of a recessed portion surface in an electronic element mounting board according to a fourth embodiment of the present disclosure.

FIG. 9 is enlarged schematic views of a part of a conductor, each illustrating an example of a shape of the conductor of the electronic element mounting board according to the fourth embodiment of the present disclosure.

FIG. 10 is a schematic plan view of an electronic component according to a fifth embodiment of the present disclosure.

FIG. 11 is a schematic cross-sectional view of the electronic component according to the fifth embodiment of the present disclosure.

FIG. 12 is an enlarged schematic plan view of the vicinity of a conductor of an electronic element mounting board according to the fifth embodiment of the present disclosure.

### DESCRIPTION OF EMBODIMENTS

### First Embodiment

### Overview of Electronic Component and Board

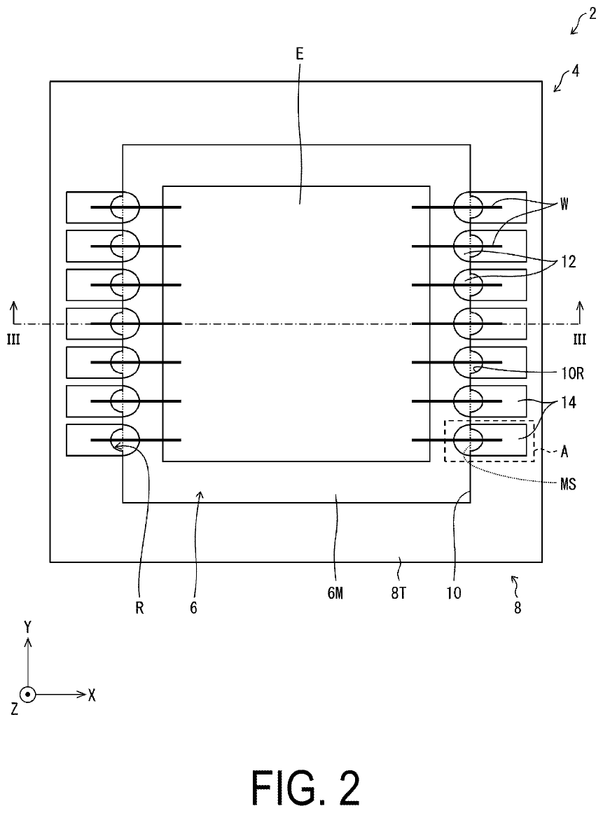

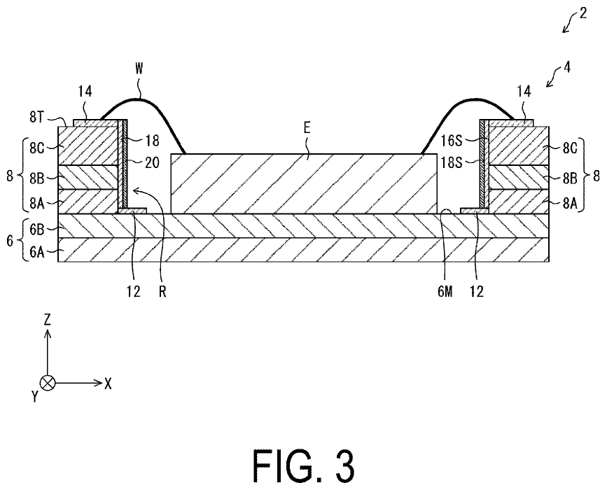

FIG. 2 is a schematic plan view illustrating an electronic component 2 according to the present embodiment. FIG. 3 is a schematic cross-sectional view of the electronic component 2 according to the present embodiment, and is a cross-sectional view taken along line III-III in FIG. 2. Schematic cross-sectional views including FIG. 3 in the present disclosure illustrate only members positioned in cross sections, and do not illustrate members positioned on a far side relative to the cross sections.

The electronic component 2 according to the present embodiment includes a board 4 and an electronic element E mounted on the board 4. The board 4 includes a bottom portion 6 and a side portion 8. In particular, the bottom portion 6 includes a mounting surface 6M on which the electronic element E is mounted. The side portion 8 is positioned surrounding the mounting surface 6M, and includes a side wall 10 rising from the bottom portion 6 as a first surface positioned on the mounting surface side. In other words, the board 4 includes the side portion 8 positioned at least partially in the vicinity of the electronic element E and surrounding the electronic element E. In other words, the board 4 according to the present embodiment is an electronic element mounting board. The schematic plan views of the electronic component in the present disclosure including FIG. 2 are plan views of the bottom portion 6 with respect to the mounting surface 6M.

For example, as illustrated in FIG. 3, the bottom portion 6 includes two layered layers, that is, bottom portion layers 6A and 6B. The side portion 8 includes three layered layers, that is, side portion layers 8A, 8B, and 8C. Accordingly, the board 4 has a structure including a total of five layers, that is, the plurality of bottom portion layers included in the bottom portion 6 and the plurality of side portion layers included in the side portion 8. However, the number of bottom portion layers included in the bottom portion 6 and the number of side portion layers included in the side portion 8 are not limited to this structure, and more than or less than the number of layers in the configuration illustrated in FIG. 3 may be provided. For example, the bottom portion 6 and the side portion 8 may each have a single-layer structure. In the board 4, the bottom portion 6 and the side portion 8 may be an integral member.

The board 4 includes lower electrodes 12 located in the bottom portion 6 and upper electrodes 14 located in a top portion 8T of the side portion 8. More particularly, the lower electrode 12 overlaps the upper electrode 14 in a plan view of the mounting surface 6M. The lower electrode 12 and the upper electrode 14 are each made of a material having electrical conductivity, such as a metal material. For example, the lower electrode 12 is formed on the mounting surface 6M of the bottom portion 6, but no limitation is intended. The lower electrode 12 may be formed on a surface of the bottom portion 6 on a side opposite to the mounting surface 6M or inside the bottom portion 6.

The electronic component 2 may include a plurality of connection members W. The connection member W may be a bonding wire. The bonding wire is made of a material having electrical conductivity, such as a metal material. Each of the upper electrodes 14 is electrically connected to the electronic element E via the bonding wire. Accordingly, in the electronic component 2, electrical conduction is established from the electronic element E to the upper electrode 14 via the bonding wire. Alternatively, the connection member W may be a bonding material. For example, when the lower electrode 12 extends below the electronic element E, the electronic element E may be flip-chip mounted on the board 4. In this case, another electronic element may be further mounted by flip-chip mounting, straddling each of the upper electrodes 14 or a plurality of the upper electrodes 14.

### Recessed Portion Surface

The side portion 8 further includes a recessed portion surface 10R recessed toward the inner side of the side portion 8 from the side wall 10 opposing the electronic element E. More particularly, the side portion 8 includes a plurality of the recessed portion surfaces 10R locally recessed from the side wall 10. Accordingly, the side portion 8 includes a plurality of locally-recessed recessed portions R that are formed on the side wall 10 side. More particularly, the recessed portion R is formed in a region surrounded by the recessed portion surface 10R and an extension surface MS located on an extension plane of the side wall 10. The board 4 includes the lower electrodes 12 and the upper electrodes 14 at positions connected to the respective recessed portion surfaces 10R. Accordingly, the lower electrodes 12 and the upper electrodes 14 are connected via the recessed portion surfaces 10R, respectively.

As described above, for example, the side wall 10 rises from a position of the mounting surface 6M surrounding the periphery of the electronic element E. Specifically, as illustrated in FIG. 2, the side wall 10 and the extension surface MS form a substantially rectangular shape in a cross section along the mounting surface 6M. However, the present invention is not limited to this, and the side portion 8 may be formed on the mounting surface 6M at a position covering a part of the periphery of the electronic element E, and for example, may be formed at a position covering only three sides of the four sides of the periphery of the electronic element E. The side wall 10 and the extension surface MS may have a substantially circular shape in a cross section along the mounting surface 6M.

### Conductor

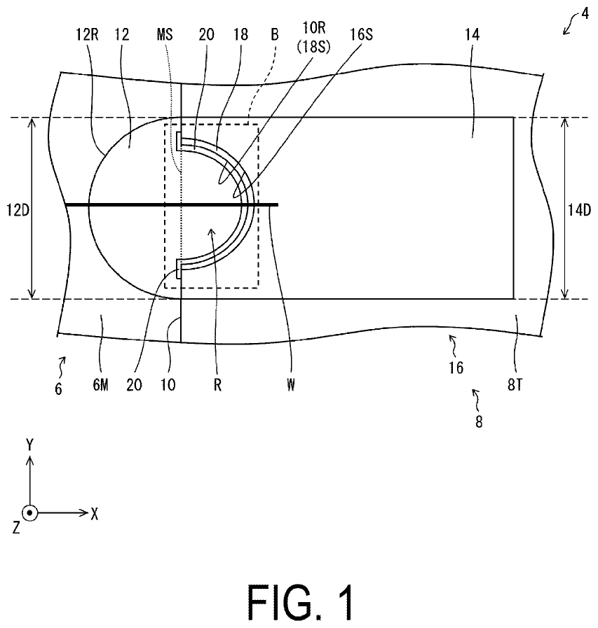

The structure of the board 4 in the vicinity of the recessed portion surface 10R will be described in more detail with reference to FIG. 1. FIG. 1 is an enlarged schematic plan view illustrating the vicinity of the recessed portion surface 10R in the board 4 according to the present embodiment, and is an enlarged schematic view of a region A illustrated in FIG. 2.

As illustrated in FIG. 1, the side portion 8 includes a side portion base 16 and a conductor 18, each of which forms a part of the side portion 8. The side portion base 16 forms a part of the side wall 10, and includes a side portion base recessed portion surface 16S recessed toward the inner side of the side portion 8 relative to the extension surface MS. The conductor 18 is made of a material having electrical conductivity, such as a metal material, and is located at least partially on the side portion base recessed portion surface 16S. Accordingly, the conductor 18 includes an outer surface 18S located on the recessed portion surface 10R. In the present embodiment, the conductor 18 is located on the entire side portion base recessed portion surface 16S. Accordingly, the outer surface 18S according to the present embodiment is the same as the recessed portion surface 10R.

Relationship between Conductor and Each Electrode

Here, the side portion base recessed portion surface 16S extends in a direction from the bottom portion 6 toward the top portion 8T of the side portion 8. Accordingly, the recessed portion surface 10R also extends in the direction from the bottom portion 6 toward the top portion 8T of the side portion 8. Here, the conductor 18 is located on the entire side portion base recessed portion surface 16S, and the lower electrodes 12 and the upper electrodes 14 are connected via the recessed portion surfaces 10R, respectively. Thus, each conductor 18 electrically connects each of the lower electrodes 12 and each of the upper electrodes 14 to each other. In other words, the lower electrode 12 is electrically connected to the upper electrode 14 via the conductor 18. More particularly, in a plan view of the mounting surface 6M, the upper electrode 14 may be formed at a position partially overlapping the conductor 18, and the lower electrode 12 may be formed inside the recessed portion R.

Thus, in the board 4, electrical conduction is established between each of the lower electrodes 12 and each of the upper electrodes 14 with a simple configuration. Therefore, the electronic component 2 has a structure in which electrical conduction from the electronic element E mounted on the board 4 by wire bonding or the like is extracted to the outside of the board 4 via the lower electrode 12, with a simpler and smaller configuration.

As illustrated in FIGS. 2, 3, for example, the lower electrode 12 according to the present embodiment may be exposed on the bottom portion 6 on the side of the mounting surface 6M relative to the recessed portion surface 10R in a plan view of the mounting surface 6M. More particularly, the lower electrode 12 may be formed on the mounting surface 6M. In this case, formation of the lower electrode 12 into the bottom portion 6 becomes easy, and formation of a through hole in the bottom portion 6 for ensuring electrical conduction between the lower electrode 12 and the conductor 18 becomes unnecessary. Therefore, with the above configuration, the board 4 can establish electrical conduction between the lower electrode 12 and the upper electrode 14 with a simpler configuration.

As maximum widths in the direction along the side wall 10, the lower electrode 12 has a width 12D and the upper electrode 14 has a width 14D. In the present embodiment, the width 12D and the width 14D may be the same. In this case, the electrical characteristics of the lower electrode 12 and the upper electrode 14 are further homogenized, and the electrical characteristics of the electronic component 2 as a whole are improved.

In the present description, “the width 12D and the width 14D are the same” does not strictly mean only a case where the width 12D and the width 14D are the same. For example, in the present description, when “the width 12D and the width 14D are the same”, a difference to a degree of a manufacturing error occurring when the lower electrode 12 and the upper electrode 14 are designed and manufactured with the maximum widths in the direction along the side wall 10 being the same is allowed. For example, when the difference between the width 12D and the width 14D is within 50 μm, the width 12D and the width 14D are the same.

### Coating Film

The board 4 further includes a coating film 20 covering the surface of the conductor 18 exposed from the side portion base 16, including the outer surface 18S. In the present embodiment, the optical reflectance of the coating film 20 is lower than the optical reflectance of the conductor 18. For example, the coating film 20 may be made of a material having a low reflectance of light included in any wavelength band of the visible light range, the infrared light range, and the ultraviolet light range with respect to the conductor 18. Specifically, the coating film 20 may be, for example, a thin film of alumina. The coating film 20 may have a function of a protective film that reduces the occurrence of defects in the conductor 18, such as oxidation or damage of the conductor 18.

The optical reflectance of the conductor 18 and the coating film 20 may be measured by the following method. For example, the outer surface of each of the conductor 18 and the coating film 20 is irradiated with light from a direction with an angle of 45 degrees with respect to the normal direction of the outer surface. Next, the intensity of the light reflected at the outer surface is measured. Next, a ratio of the intensity of the reflected light to the intensity of the irradiated light is calculated, and this ratio is defined as the optical reflectance.

### Specific Example of Recessed Portion Surface

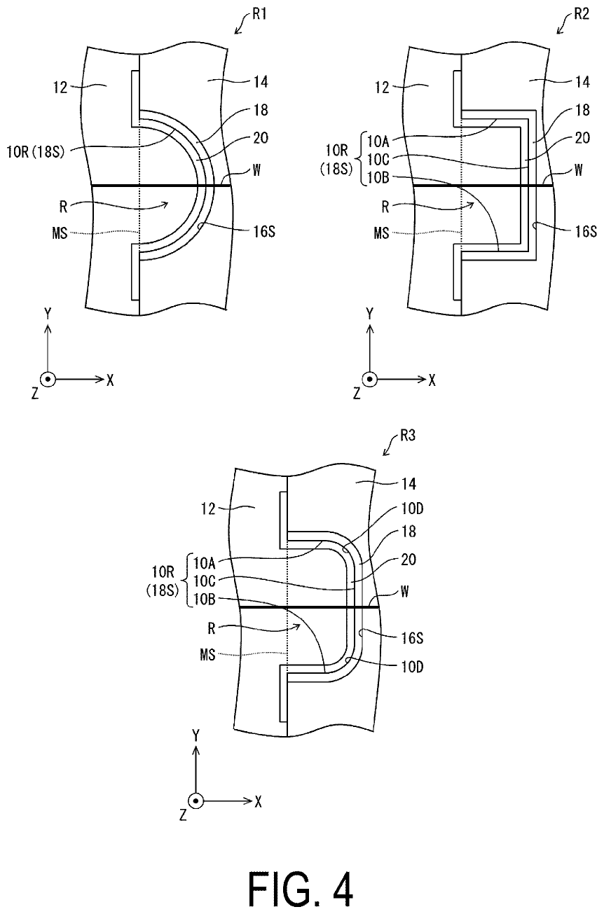

Examples of specific shapes of the recessed portion R and the recessed portion surface 10R will be described with reference to FIG. 4. FIG. 4 is enlarged schematic views each illustrating the vicinity of the recessed portion surface 10R in the board 4 in a plan view of the mounting surface 6M, and are enlarged views of a region B illustrated in FIG. 1. Specific examples R1, R2, and R3 of the recessed portions R illustrated in FIG. 4 are different only in terms of the shape of each member. The function, material, and the like of each member are the same.

As illustrated in the specific example R1 of the recessed portion R in FIG. 4, for example, the recessed portion R according to the present embodiment has a substantially semi-cylindrical shape. In this case, the side portion base recessed portion surface 16S includes a substantially semicircular curved portion in a cross section along the mounting surface 6M. Accordingly, since the recessed portion surface 10R is a curved surface, the recessed portion surface 10R has a curved shape in a cross section along the mounting surface 6M. In other words, the outer surface 18S includes a curved surface, and the outer surface 18S has a curved shape in a cross section along the mounting surface 6M. As described above, since the outer surface 18S has the curved shape in a cross section along the mounting surface 6M, the board 4 can reduce the occurrence of defects such as cracks in the members formed in the recessed portion R.

In this case, as illustrated in FIG. 1, the lower electrode 12 may have an outer shape 12R having a curved shape on the electronic element E side in a plan view of the mounting surface 6M. With the above configuration, the electrical characteristics of the lower electrode 12 and the conductor 18 are further homogenized, and the electrical characteristics of the electronic component 2 as a whole are improved.

As illustrated in the specific example R2 of the recessed portion R in FIG. 4, for example, the recessed portion R according to the present embodiment may have a substantially rectangular cuboid shape. In this case, the side portion base recessed portion surface 16S has a partially substantially rectangular shape in a cross section along the mounting surface 6M. Therefore, the recessed portion surface 10R includes a first recessed portion side surface 10A, a second recessed portion side surface 10B, and a recessed portion connection surface 10C connecting the first recessed portion side surface 10A and the second recessed portion side surface 10B. The first recessed portion side surface 10A and the second recessed portion side surface 10B are each located up to the side wall 10. In this case, since the first recessed portion side surface 10A, the second recessed portion side surface 10B, and the recessed portion connection surface 10C are all flat surfaces, the recessed portion surface 10R has a linear shape in a cross section along the mounting surface 6M. In other words, the outer surface 18S has a linear shape in a cross section along the mounting surface 6M.

As illustrated in the specific example R3 of the recessed portion R in FIG. 4, for example, a first curved surface region connected to the first recessed portion side surface 10A and a second curved surface region connected to the second recessed portion side surface 10B may be located on the recessed portion connection surface 10C in the specific example R2. Specifically, as illustrated in the specific example R3 in FIG. 4, the recessed portion connection surface 10C may have a recessed portion curved surface 10D in each of the first curved surface region and the second curved surface region. In this case, since the recessed portion surface 10R includes both a curved surface and a flat surface, the recessed portion surface 10R has both a linear shape and a curved shape in a cross section along the mounting surface 6M. In other words, the outer surface 18S has both a linear shape and a curved shape in a cross section along the mounting surface 6M.

### Specific Examples of Material

The bottom portion 6 and the side portion base 16 may contain, for example, an electrically insulating ceramic or a resin containing plastic. Examples of the electrically insulating ceramic include an aluminum oxide sintered body, a mullite sintered body, a silicon carbide sintered body, an aluminum nitride sintered body, a silicon nitride sintered body, and a glass ceramic sintered body. Examples of the resin include an epoxy resin, a polyimide resin, an acrylic resin, a phenol resin, and a fluorine-based resin. Examples of the fluorine-based resin include a polyester resin and a tetrafluoroethylene resin.

The lower electrode 12 and the upper electrode 14 may be made of any of, for example, tungsten (W), molybdenum (Mo), manganese (Mn), silver (Ag), and copper (Cu), or an alloy containing at least one selected from the group consisting of them. The conductor 18 may be made of the same material as that of the lower electrode 12 or the upper electrode 14.

### Effects Achieved by Board

For example, when the conductor is exposed on an inner surface surrounding the electronic element, which is one of the surfaces of the board on which the electronic element is mounted, light may scatter due to light incident on the surface of the conductor. Thus, unnecessary scattered light may be incident on the electronic element mounted on the board, or unnecessary scattered light may be emitted from the electronic element.

The board 4 according to the present embodiment includes the conductor 18 including the outer surface 18S on the inner side of the side portion 8 relative to the extension surface MS of the side wall 10. Accordingly, when light is incident on the outer surface 18S of the conductor 18 from the outside of the board 4 and is diffusely reflected at the outer surface 18S, the board 4 reduces the probability that the diffusely reflected light travels toward the electronic element E.

More particularly, when the side portion base 16 is made of an electrically insulating ceramic and the conductor 18 is made of a metal material, the optical reflectance at the surface of the conductor 18 is generally higher than that at the surface of the side portion base 16. Accordingly, since the outer surface 18S having a higher optical reflectance than that of the side portion base 16 is located on the recessed portion surface 10R located on the inner side of the side portion 8 relative to the extension surface MS of the side wall 10, the probability that the light diffusely reflected at the side portion 8 travels toward the electronic element E is more efficiently reduced.

With the above configuration, the board 4 according to the present embodiment can reduce the incidence of unintended light on the electronic element E located on the mounting surface 6M. Therefore, the board 4 improves the element characteristics of the mounted electronic element E.

The electronic component 2 includes a structure for extracting electrical conduction from the electronic element E to the outside of the board 4 via the connection member W, such as a bonding wire, and the conductor 18. The board 4 reduces the probability that the light diffusely reflected on the side portion 8 travels toward the electronic element E. Therefore, the electronic component 2 can improve the characteristics of the electronic element E while achieving downsizing.

Here, the electronic element E may be an optical element that receives visible light, infrared light, ultraviolet light, or the like. When the electronic element E is included as an optical element, the electronic component 2 efficiently reduces the incidence of unintended light on the electronic element E, and therefore improvement of the characteristics of the electronic element E is more effectively achieved.

The electronic element E may be an element that emits light. In this case, the board 4 reduces diffused reflection, at the side portion 8, of light emitted from the mounted electronic element E. Therefore, the board 4 reduces extraction of unintended light, excluding light emitted from the mounted electronic element E, from the electronic component 2, and improves the element characteristics of the electronic element E.

The board 4 according to the present embodiment includes the coating film 20 covering the outer surface 18S. The coating film 20 has lower optical reflectance than the conductor 18. Accordingly, diffused reflection of light at the coating film 20 is less likely to occur than diffused reflection of light at the outer surface 18S. Therefore, by covering the outer surface 18S with the coating film 20, the board 4 can more efficiently reduce diffused reflection of light at the side portion 8. Therefore, the board 4 according to the present embodiment can further reduce incidence, on the electronic element E located on the mounting surface 6M, of light diffusely reflected at the side portion 8, and further improve the element characteristics of the mounted electronic element E.

The coating film 20 may cover a position including the outer surface 18S of the surfaces of the side portion 8, and may further cover a part consisting of the side portion base 16 of the surfaces of the side portion 8, for example. In this case, the coating film 20 may be made of a material having a lower optical reflectance than that of the side portion base 16. With the above configuration, the coating film 20 can reduce diffused reflection of light also at the inner surface of the side portion base 16 on the electronic element E side. Therefore, with the above configuration, the board 4 can further reduce incidence, on the electronic element E located on the mounting surface 6M, of light diffusely reflected at the side portion 8, and further improve the element characteristics of the mounted electronic element E.

The coating film 20 may be further formed at a position covering the surfaces of the lower electrode 12 and the upper electrode 14. In this case, since the board 4 can reduce the probability that light diffusely reflected at the surfaces of the lower electrode 12 and the upper electrode 14 is incident on the electronic element E, the board 4 further improves the element characteristics of the mounted electronic element E.

In the present embodiment, the recessed portion surface 10R extends in a direction from the bottom portion 6 toward the top portion 8T of the side portion 8. With the above configuration, the distance between the lower electrode 12 and the upper electrode 14 becomes shorter than that when the recessed portion surface 10R is formed obliquely with respect to the direction. Therefore, with the above configuration, the formation area of the recessed portion surface 10R is reduced and thus the area of the outer surface 18S is reduced. Therefore, since the above configuration reduces diffused reflection of light at the side portion 8, the above configuration improves the characteristics of the electronic element E.

### Manufacturing Method of Board and Electronic Component

An example of a manufacturing method of the board 4 and the electronic component 2 according to the present embodiment will be described. An example of the manufacturing method illustrated in the present embodiment is a manufacturing method of the board 4 using a multi-piece wiring board.
(a) First, a ceramic green sheet used for the bottom portion 6 of the board 4 and the side portion base 16 is formed. For example, when the bottom portion 6 and the side portion base 16 are made of an electrically insulating ceramic, the material of the electrically insulating ceramic is kneaded to form a slurry mixture. Next, the mixture is shaped by a molding method such as a doctor blade method or a calendering roll method to obtain a ceramic green sheet for multi-piece molding. When the bottom portion 6 and the side portion base 16 are made of, for example, a resin, the bottom portion 6 and the side portion base 16 may be manufactured by shaping the resin by press molding using a mold by a transfer molding method, an injection molding method, or the like.
(b) Next, the ceramic green sheet obtained in the process (a) described above is coated or filled with a metal paste by a screen printing method or the like. The metal paste may be applied to, for example, parts to be the lower electrode 12 and the upper electrode 14. The metal paste may be prepared by adding an appropriate solvent and a binder to a metal powder consisting of the above-described metal material and kneading them to adjust the viscosity to an appropriate value. The metal paste may contain glass or a ceramic to increase the joint strength between the bottom portion 6 and the side portion base 16. When the bottom portion 6 and the side portion base 16 are made of resin, the lower electrode 12 and the upper electrode 14 may be formed by, for example, a sputtering method or a vapor deposition method.
(c) Next, the above-described green sheet is processed by using a die or the like. More particularly, in the green sheet to be the side portion base 16, a first opening is formed at a position where the side portion base recessed portion surface 16S is to be formed.
(d) Next, a metal paste to be the conductor 18 is applied to the inner surface of the first opening formed in the green sheet. The metal paste to be the conductor 18 may contain the same material as that of the metal paste to be the lower electrode 12 and the upper electrode 14. For example, a thin film of the metal paste may be formed only on the inner surface of the first opening by applying the metal paste to the first opening or filling the first opening with the metal paste and then suctioning some of the metal paste.
(e) Next, a second opening is further provided at a predetermined position of the ceramic green sheet using a mold, by punching, by a laser, or the like. More particularly, in the present embodiment, the ceramic green sheet in which the metal paste to be the conductor 18 is formed on the inner surface of the first opening is cut across the first opening in a plan view of the ceramic green sheet. Thus, an opening is formed in the ceramic green sheet by the first opening and the second opening. A part of the inner surface of the opening becomes the side wall 10 of the board 4 according to the present embodiment.
(f) Next, ceramic green sheets to be the bottom portion 6 and the side portion base 16 are layered and pressurized. For example, five ceramic green sheets may be layered to form a laminate of ceramic green sheets that becomes each of the bottom portion layers 6A and 6B and the side portion layers 8A, 8B, and 8C. Here, an opening may be formed in the laminate of the ceramic green sheets.
(g) Next, this ceramic green sheet laminate is fired at a temperature of about 1500° C. to 1800° C. to obtain a multi-piece wiring board in which a plurality of the boards 4 are arrayed. Through this process, the above-described metal paste is fired simultaneously with the ceramic green sheet to be the board 4, and becomes the lower electrode 12, the upper electrode 14, and the conductor 18.
(h) Next, the multi-piece wiring board obtained by firing is split to manufacture the plurality of boards 4. For this splitting step, a method in which split grooves are formed in the multi-piece wiring board along portions to become the outer edges of the board 4 and the multi-piece wiring board is broken and split along these division grooves can be adopted, or a dicing method or the like can be adopted. Before or after the above-described multi-piece wiring board is split into the plurality of boards 4, the coating film 20 may be deposited on the surfaces of the lower electrode 12, the upper electrode 14, and the conductor 18. The coating film 20 may be formed by, for example, a coating method, a sputtering method, or a vapor deposition method.
(i) Next, the electronic element E is mounted on the mounting surface 6M of the board 4. The mounting surface 6M and the electronic element E may be bonded to each other with an adhesive or the like. The electronic element E is electrically connected to each of the upper electrodes 14 by the connection members W, for example, bonding wires.

The electronic component 2 can be manufactured by preparing the board 4 and mounting the electronic element E as in the processes (a) to (i) described above. The order of the above processes (a) to (i) is not specified as long as the order is a machinable order. For example, in the manufacturing method of the board 4, after the ceramic green sheets are layered, formation of the first opening, application of the metal paste to the inner surface of the first opening and suction of the metal paste, and formation of the second opening may be sequentially performed.

The electronic component 2 can be mounted on an electronic apparatus by a known method. Since an electronic apparatus including the electronic component 2 according to the present embodiment includes the electronic element E having improved characteristics, the electronic apparatus has higher quality.

### Variation

### Variation of Side Portion

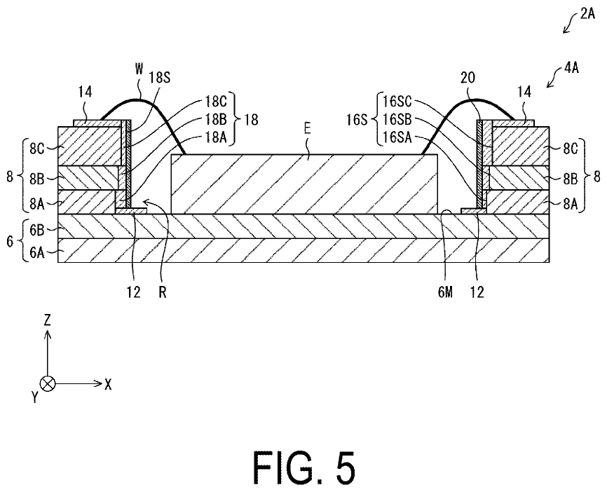

FIG. 5 is a schematic cross-sectional view of an electronic component 2A according to a variation of the present embodiment, and is a cross-sectional view illustrating a cross section corresponding to a cross section taken along line III-III in FIG. 2. In the present description, each member having the same function is denoted by the same name and assigned with the same reference sign, and explanation is not repeated as long as there is no difference in the configuration.

The electronic component 2A according to the present variation is different from the electronic component 2 according to the present embodiment only in terms of including a board 4A in place of the board 4. In the board 4A, as compared with the board 4 according to the present embodiment, at least one of the side portion layers 8A, 8B, and 8C is different from any of the other side portion layers 8A, 8B, and 8C in terms of its position in the direction parallel to the mounting surface 6M. For example, as illustrated in FIG. 5, in the present embodiment, the formation positions of each of the side portion layers 8A, 8B, and 8C in a plan view of the mounting surface 6M are different from one another.

Due to this, the thickness of the conductor 18 from the outer surface 18S is different in at least two cross sections parallel to the mounting surface 6M. Specifically, as illustrated in FIG. 5, conductors 18A, 18B, and 18C are formed on side portion base recessed portion surfaces 16SA, 16SB, and 16SC of the side portion layers 8A, 8B, and 8C, respectively. Here, the outer surface 18S of the conductor 18 formed of the conductors 18A, 18B, and 18C is located on substantially the same plane. Therefore, the thicknesses of the conductors 18A, 18B, and 18C are different in the direction parallel to the mounting surface 6 M.

Except for the above points, the board 4A according to the present variation has the same configuration as that of the board 4 according to the present embodiment. Therefore, the board 4A according to the present variation improves the characteristics of the mounted electronic element E for the same reason as the board 4 according to the present embodiment.

The board 4A can include a structure in which the thickness of the conductor 18 in the direction parallel to the mounting surface 6M is large on the bottom portion 6 side and small on the top portion 8T side of the side portion 8. In this case, in the board 4A, the contact area between the lower electrode 12 and the conductor 18 can be increased without increasing the formation area of each of the lower electrode 12 and the upper electrode 14. Therefore, with the above configuration, the board 4A improves the electrical characteristics of the lower electrode 12 while achieving downsizing.

The board 4A may be manufactured by partially changing the manufacturing method of the board 4 described above. For example, in the manufacturing method of the board 4 described above, the layered positions of the ceramic green sheets to become the side portion layers 8A, 8B, and 8C may be shifted from one another. Here, after forming a laminate of ceramic green sheets to become the side portion layers 8A, 8B, and 8C with the layered positions shifted from one another, the metal paste may be applied to the inner surface of the first opening. Thus, the conductors 18 having different widths in the direction parallel to the mounting surface 6M may be formed in each of the side portion layers 8A, 8B, and 8C.

### Second Embodiment

### Metal Layer

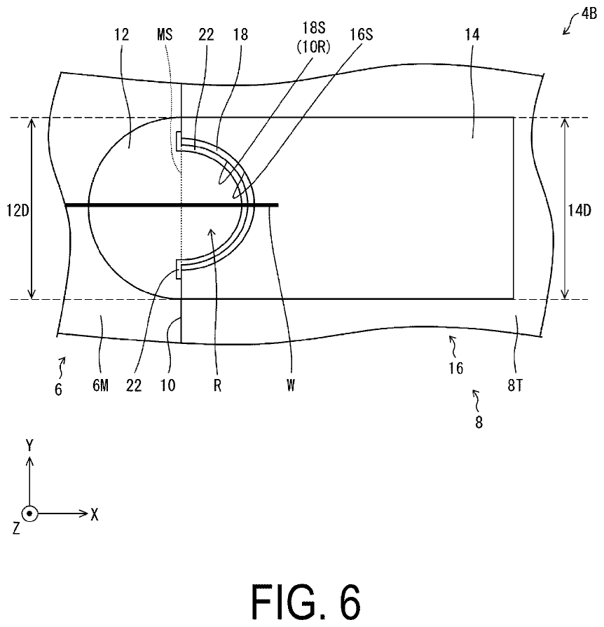

FIG. 6 is an enlarged schematic plan view illustrating the vicinity of the recessed portion surface 10R in a board 4B according to the present embodiment, and is an enlarged schematic view of a region corresponding to the region A illustrated in FIG. 2.

The board 4B according to the present embodiment is different from the board 4 according to the first embodiment only in including a metal layer 22 in place of the coating film 20. The metal layer 22 can be formed by forming a single metal or an alloy of a plurality of metals on the outer surface 18S by a plating method or the like. In other words, in the manufacturing method of the board 4 described above, the board 4B may be manufactured by a manufacturing method in which the formation process of the coating film 20 is replaced with the formation process of the metal layer 22.

The board 4B according to the present embodiment also includes the conductor 18 including the outer surface 18S located on the inner side of the side portion 8 relative to the extension surface MS of the side wall 10. Therefore, the board 4B according to the present embodiment improves the characteristics of the mounted electronic element E for the same reason as the board 4 according to the present embodiment. The metal layer 22 may be a metal having high electrical conductivity, such as gold. In this case, the metal layer 22 of the board 4B can improve electric conductivity in the conductor 18. Therefore, the board 4B can improve the electrical characteristics in the conductor 18.

### Third Embodiment

### Variation of Conductor

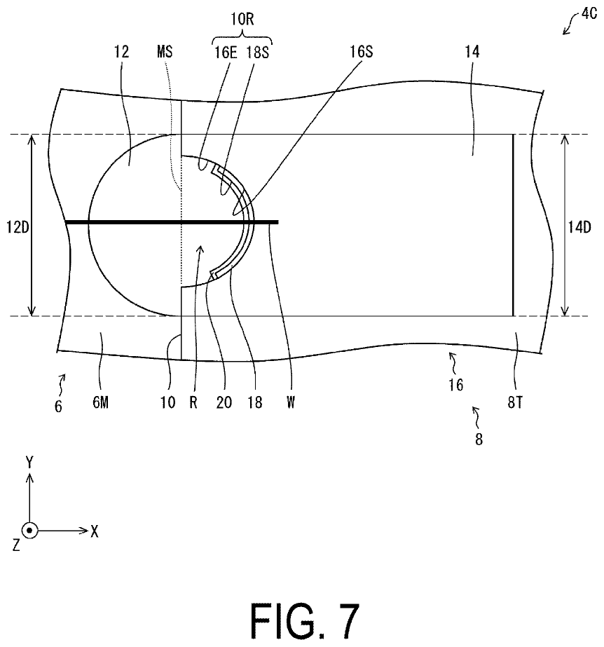

FIG. 7 is an enlarged schematic plan view illustrating the vicinity of the recessed portion surface 10R of a board 4C according to the present embodiment, and is an enlarged schematic view of a region corresponding to the region A illustrated in FIG. 2.

The board 4C according to the present embodiment is different from the board 4 according to the first embodiment in that the outer surface 18S of the conductor 18 is a part of the recessed portion surface 10R. More particularly, the conductor 18 is formed only on a part of the side portion base recessed portion surface 16S. Due to this, an exposed surface 16E exposed from the conductor 18 is formed at the side portion base recessed portion surface 16S. Accordingly, the recessed portion surface 10R in the present embodiment includes the outer surface 18S and the exposed surface 16E. The coating film 20 may be formed at a position covering the conductor 18, including the outer surface 18S, and may be formed only on a part of the recessed portion surface 10R, as illustrated in FIG. 7.

In a cross section along the mounting surface 6M, the outer surface 18S according to the present embodiment is away from the side wall 10. In other words, the conductor 18 does not extend up to the side wall 10 and does not overlap the extension surface MS. More particularly, the conductor 18 is formed on a part of the side portion base recessed portion surface 16S on the inner side of the side portion 8 relative to the extension surface MS, in a plan view of the mounting surface 6M. Accordingly, the exposed surface 16E is formed on a side close to the side wall 10 relative to the outer surface 18S.

Except for the above points, the board 4C according to the present embodiment has the same configuration as that of the board 4 according to the present embodiment.

The board 4C according to the present embodiment includes the conductor 18 including the outer surface 18S on a part of the recessed portion surface 10R. With the above configuration, the board 4C more efficiently reduces the probability that the light diffusely reflected at the side portion 8 travels toward the electronic element E. Therefore, the board 4C according to the present embodiment more efficiently improves the characteristics of the electronic element E to be mounted. Since reduction in the volume of the conductor 18 to be formed can reduce the material used for forming the conductor 18 in the board 4C according to the present embodiment, the manufacturing cost can be reduced.

The board 4C according to the present embodiment includes the conductor 18 including the outer surface 18S away from the side wall 10 in a cross section along the mounting surface 6M. With the above configuration, in the board 4C, the distance between the outer surface 18S of the recessed portion surface 10R and the mounted electronic element E can be further increased. Therefore, the board 4C further efficiently reduces the probability that the light diffusely reflected at the side portion 8 travels toward the electronic element E.

The board 4C may be manufactured by partially changing the manufacturing method of the board 4 described above. For example, in the manufacturing method of the board 4 described above, the metal paste may be applied to a part of the inner surface of the first opening by masking a part of the inner surface of the first opening in the process of applying the metal paste to the first opening of the ceramic green sheet.

### Fourth Embodiment

### Another Variation of Conductor

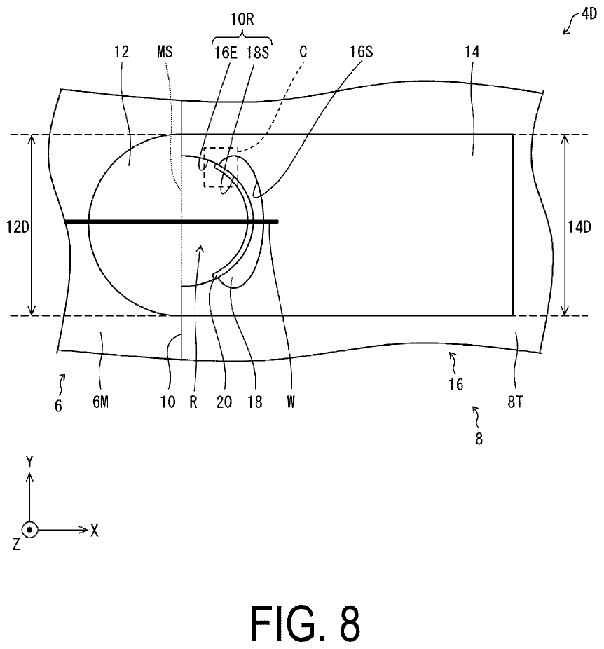

FIG. 8 is an enlarged schematic plan view illustrating the vicinity of the recessed portion surface 10R of a board 4D according to the present embodiment, and is an enlarged schematic view of a region corresponding to the region A illustrated in FIG. 2.

The board 4D according to the present embodiment is different from the board 4C according to the previous embodiment in that the board 4D further includes the conductor 18 located in a region of the side portion 8 away from the side wall 10 in a cross section along the mounting surface 6M. In particular, the conductor 18 is partly applied at an inner side of the side portion 8 relative to the extension surface MS in a recessed portion space formed by the side portion base recessed portion surface 16S. In other words, in a plan view of the mounting surface 6M, the conductor 18 occupies a partial region on the inner side of the side portion 8 relative to the extension surface MS in the recessed portion space formed by the side portion base recessed portion surface 16S. Except for the above configuration, the board 4D according to the present embodiment has the same configuration as that of the board 4C according to the previous embodiment. In this case, the side portion base recessed portion surface 16S is a partially imaginary continuous surface that does not include the outer shape of a through hole filled with the conductor 18, and the side portion base recessed portion surface 16S refers to a surface that coincides with the outer surface 18S filled with the conductor 18 and exposed to the front surface. In other words, the conductor 18 has a thickness in a direction away from the side wall 10.

The board 4D according to the present embodiment includes the conductor 18 that fills a part of the recessed portion formed by the side portion base recessed portion surface 16S. With the above configuration, at a position where the side portion base 16 and the conductor 18 are in contact with each other, the board 4D reduces deformation of the side portion 8, and thus reduces deformation of the recessed portion surface 10R. Therefore, the board 4D reduces deformation of the space formed by the side wall 10, to which the electronic element E is mounted.

The board 4D may be manufactured by partially changing the manufacturing method of the board 4 described above. For example, in the manufacturing method of the board 4 described above, after the first opening of the ceramic green sheet is filled with the metal paste, the ceramic green sheet may be cut at a position including the metal paste to form a third opening. Thus, the ceramic green sheet in which a part of the opening is filled with the metal paste can be manufactured.

### Specific Examples of Vicinity of End Portion of Conductor

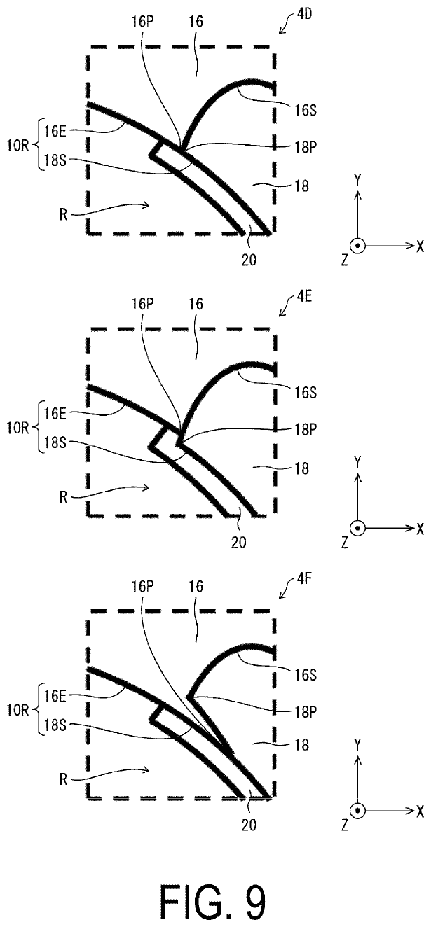

Examples of shapes of the side portion base 16 and the conductor 18 according to the present embodiment will be described with reference to FIG. 9. FIG. 9 is enlarged schematic views illustrating a part of the conductor 18, and is enlarged schematic views of a region C illustrated in FIG. 8. FIG. 9 illustrates enlarged schematic views of the board 4D according to the present embodiment together with a board 4E according to a first variation of the present embodiment and a board 4F according to a second variation. The board 4E according to a variation of the present embodiment and the board 4F according to another variation have the same configuration except for the shapes of the side portion base 16, the conductor 18, and the coating film 20.

FIG. 9 illustrates the conductor 18, with the vicinity of an end portion 18P near the extension surface MS enlarged. The conductor 18 includes the end portion 18P on each of the upper side and the lower side in FIG. 8, for example. Here, FIG. 9 illustrates only the vicinity of one end portion 18P of the two end portions 18P of the conductor 18. However, in the present embodiment, the positional relationship between the side portion base 16 and the conductor 18 to be described later may be the same at both end portions near the extension surface MS.

For example, as illustrated in the enlarged schematic views of the board 4D and the board 4E in FIG. 9, in a cross section along the mounting surface 6M, the end portion 18P of the conductor 18 according to the present embodiment and that according to the first variation are positioned on the recessed portion surface 10R. In other words, both end portions on the side of the side wall 10 of the conductor 18 according to the present embodiment and the first variation are positioned on the recessed portion surface 10R. More particularly, the end portion 18P of the conductor 18 according to the present embodiment is in contact with an end portion 16P of the exposed surface 16E on the inner side of the side portion 8. Accordingly, in the board 4D according to the present embodiment, the recessed portion surface 10R is smoothly connected between the exposed surface 16E and the outer surface 18S. On the other hand, in the board 4E according to the first variation, the end portion 18P of the conductor 18 protrudes toward the side wall 10 relative to the end portion 16P of the exposed surface 16E.

For example, as illustrated in the enlarged schematic view of the board 4F of FIG. 9, in a cross section along the mounting surface 6M, in the board 4F according to the second variation, the end portion 18P of the conductor 18 is positioned inward of the side portion 8 relative to the recessed portion surface 10R. In other words, both end portions on the side of the side wall 10 of the conductor 18 according to the second variation are positioned inward of the side portion 8 relative to the recessed portion surface 10R. Accordingly, the end portion 16P of the exposed surface 16E according to the second variation reaches the recessed portion surface 10R, but the end portion 18P of the conductor 18 does not reach the recessed portion surface 10R. With this configuration, the board 4F according to the second variation can further reduce the area of the outer surface 18S exposed from the side portion base 16.

### Fifth Embodiment

### Side Portion Including No Recessed Portion Surface

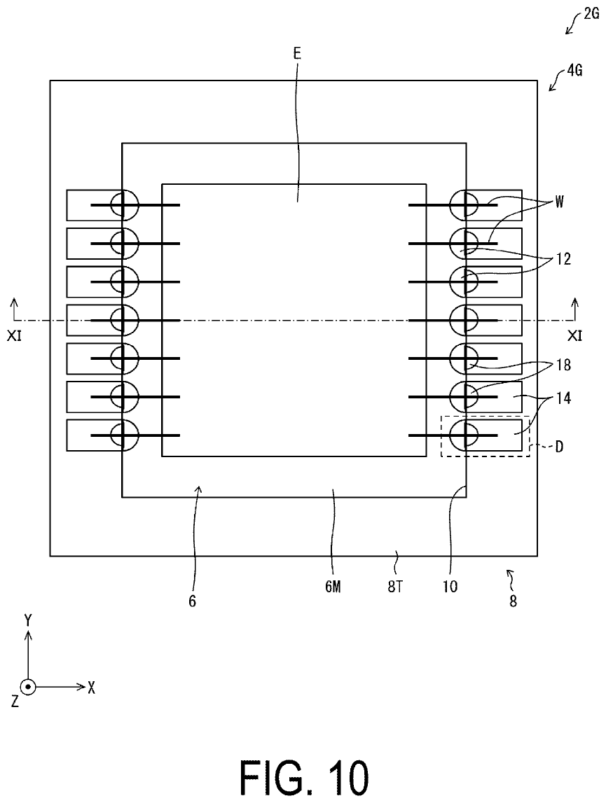

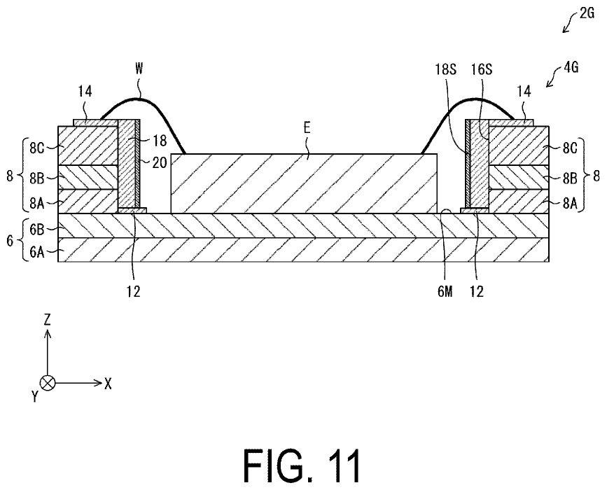

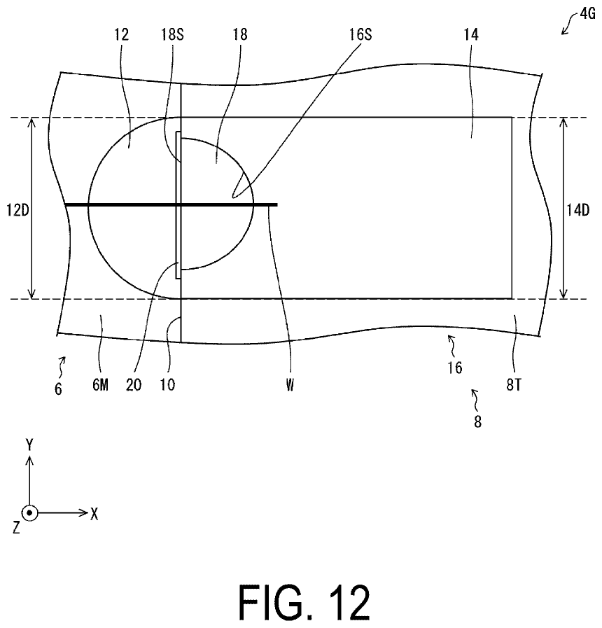

FIG. 10 is a schematic plan view illustrating an electronic component 2G according to the present embodiment. FIG. 11 is a schematic cross-sectional view of the electronic component 2G according to the present embodiment, and is a cross-sectional view taken along line XI-XI in FIG. 10. FIG. 12 is an enlarged schematic view illustrating the vicinity of the conductor 18 of a board 4G according to the present embodiment, and is an enlarged schematic view of a region D illustrated in FIG. 10.

The electronic component 2G according to the present embodiment is different from the electronic component 2 according to the present embodiment only in including the board 4G in place of the board 4. The board 4G is different from the board 4 according to the present embodiment in terms of the shape of the conductor 18.

More particularly, the outer surface 18S of the conductor 18 according to the present embodiment reaches substantially the same plane as the front surface of the side of the side wall 10 of the side portion base 16. For example, as illustrated in detail in FIG. 12, in particular, the conductor 18 fills the recessed portion space formed by the side portion base recessed portion surface 16S of the side portion base 16. Accordingly, the recessed portion R is not formed in the side portion 8 of the board 4G, and the side portion 8 does not have the recessed portion surface 10R. In other words, the side wall 10 and the outer surface 18S are substantially flush with each other. The board 4 according to the present embodiment includes the coating film 20 at a position at least partially covering the side wall 10, including a position covering the outer surface 18S.

Except for the above points, the board 4G according to the present embodiment has the same configuration as that of the board 4 according to the first embodiment.

The board 4G according to the present embodiment includes the coating film 20 covering the outer surface 18S. Accordingly, for the same reason as the reason described in the first embodiment, the board 4G can more efficiently reduce diffused reflection of light at the side portion 8. Therefore, the board 4G according to the present embodiment can reduce incidence, on the electronic element E located on the mounting surface 6M, of light diffusely reflected at the side portion 8, and improves the element characteristics of the mounted electronic element E.

The board 4G may be manufactured by partially changing the manufacturing method of the board 4 described above. For example, in the manufacturing method of the board 4 described above, after the first opening of the ceramic green sheet is filled with the metal paste, the second opening may be formed in the ceramic green sheet without suctioning the metal paste.

The present disclosure is not limited to each of the embodiments described above, and various modifications can be made within the scope indicated by the claims, and an embodiment obtained by appropriately combining technical means disclosed in different embodiments is also included in a technical scope of the present disclosure.

### REFERENCE SIGNS

2 Electronic component
4 Board (electronic element mounting board)
6 Bottom portion
6M Mounting surface
8 Side portion
10 Side wall (first surface)
10R Recessed portion surface
12 Lower electrode
14 Upper electrode
18 Conductor
18S Outer surface
20 Coating film

1. An electronic element mounting board comprising:
a bottom portion including a mounting surface on which an electronic element is mounted;
a side portion positioned surrounding the mounting surface of the bottom portion, and including a first surface located on a side of the mounting surface and a recessed portion surface recessed from the first surface; and
a conductor forming a part of the side portion and including an outer surface located on the recessed portion surface.

2. The electronic element mounting board according to claim 1, further comprising:
a coating film covering the outer surface, wherein
an optical reflectance of the coating film is lower than an optical reflectance of the conductor.

3. The electronic element mounting board according to claim 1, wherein the recessed portion surface extends in a direction from the bottom portion toward a top portion of the side portion.

4. The electronic element mounting board according to claim 3, wherein, in a cross section along the mounting surface, the outer surface comprises a part of the recessed portion surface.

5. The electronic element mounting board according to claim 4, wherein, in a cross section along the mounting surface, the outer surface is located away from the first surface.

6. The electronic element mounting board according to claim 5, wherein, in a cross section along the mounting surface, the conductor is located in a region of the side portion away from the first surface.

7. The electronic element mounting board according to claim 6, wherein, in a cross section along the mounting surface, both end portions of the conductor, located on a side of the first surface, are located on the recessed portion surface.

8. The electronic element mounting board according to claim 6, wherein, in a cross section along the mounting surface, both end portions of the conductor, located on a side of the first surface, are located on an inner side of the side portion relative to the recessed portion surface.

9. The electronic element mounting board according to claim 3, wherein, in a cross section along the mounting surface, the outer surface has a curved shape.

10. The electronic element mounting board according to claim 3, wherein, in a cross section along the mounting surface, the outer surface has a linear shape.

11. The electronic element mounting board according to claim 3, wherein a thickness of the conductor from the outer surface is different between two cross sections parallel to the mounting surface.

12. The electronic element mounting board according to claim 11, wherein
the side portion includes a plurality of layered side portion layers, and
at least one of the plurality of side portion layers is different from at least one of other side portion layers in terms of a position in a direction parallel to the mounting surface.

13. The electronic element mounting board according to claim 3, wherein
the recessed portion surface includes a first recessed portion side surface and a second recessed portion side surface, each of which being located up to the first surface, and a recessed portion connection surface connecting the first recessed portion side surface and the second recessed portion side surface, and
the recessed portion connection surface includes a first curved surface region connected to the first recessed portion side surface and a second curved surface region connected to the second recessed portion side surface.

14. An electronic element mounting board comprising:
a bottom portion including a mounting surface on which an electronic element is mounted;
a side portion positioned surrounding the mounting surface of the bottom portion and including a first surface located on a side of the mounting surface;
a conductor including an outer surface located up to the first surface at a part of the side portion; and
a coating film covering the outer surface, wherein
an optical reflectance of the coating film is lower than an optical reflectance of the conductor.

15. The electronic element mounting board according to claim 1, further comprising:
an upper electrode positioned at the top portion of the side portion; and
a lower electrode positioned, on the bottom portion, overlapping the upper electrode and electrically connected to the upper electrode via the conductor in a plan view of the mounting surface.

16. The electronic element mounting board according to claim 15, wherein the upper electrode and the lower electrode have an identical maximum width along the first surface.

17. The electronic element mounting board according to claim 15, wherein, in a plan view of the mounting surface, the lower electrode is exposed on the bottom portion on a side of the mounting surface relative to the side portion.

18. The electronic element mounting board according to claim 15, wherein the outer surface has a curved shape in a cross section along the mounting surface, and an outer shape of the lower electrode is a curved shape in a plan view of the mounting surface.

19. An electronic component comprising:
the electronic element mounting board described in claim;
the electronic element located on the mounting surface; and
a plurality of connection members, wherein
each of a plurality of the upper electrodes is electrically connected to the electronic element via the connection member.

20. (canceled)

21. An electronic apparatus comprising the electronic component described in claim 19.
